(19) United States
(12) Patent Application Publication
(10) Pub. No.: US 2011/0124952 A1
(43) Pub. Date: May 26, 2011

(54) INFANT WARMER

(75) Inventor: Biju Padmanabha Panicker, Bangalore (IN)

(73) Assignee: GENERAL ELECTRIC COMPANY, Schenectady, NY (US)

(21) Appl. No.: 12/623,901

(22) Filed: Nov. 23, 2009

(51) Int. Cl. A61G 11/00; F26B 3/28; F01K 11/00; H01L 31/042

(52) U.S. Cl. 600/22; 392/407; 60/664; 136/244

(57) ABSTRACT

An infant warmer system include a heater canopy comprising a solar panel configured to convert solar energy into electricity, and a heater operatively connected to the solar panel. The heater is powered by the electricity from the solar panel and/or electricity from a steam generator, and is configured to provide radiant energy in the infrared spectrum to impinge upon and thereby warm an infant. The heater canopy also includes a controller operatively connected to the heater. The controller is configured to regulate the temperature of the heater such that the infant may be maintained within a selectable temperature range. The heater canopy also includes an attachment member configured to secure the heater canopy to a wall during operation.

### BACKGROUND OF THE INVENTION

The subject matter disclosed herein relates to an infant warming apparatus that is particularly well suited for use in developing countries.

Warming devices may be implemented to warm an infant and to supply the necessary heat to maintain the infant within a predetermined temperature. Infant warmers commonly have an overhead radiant heater that is located above the infant and which thus radiates energy in the infrared spectrum to impinge upon the infant to maintain the predetermined temperature.

One problem with conventional infant warmers is that they rely on a consistent source of electricity in order to remain operational. This problem is highlighted in developing countries in which more conventional electricity sources may be unavailable or unreliable.

### BRIEF DESCRIPTION OF THE INVENTION

The above-mentioned shortcomings, disadvantages and problems are addressed herein which will be understood by reading and understanding the following specification.

In an embodiment, a heater canopy for a warmer system includes a solar panel configured to convert solar energy into electricity, and a heater operatively connected to the solar panel. The heater is powered by the electricity from the solar panel, and is configured to provide radiant energy in the infrared spectrum to impinge upon and thereby warm an infant. The heater canopy also includes a controller operatively connected to the heater. The controller is configured to regulate the temperature of the heater such that the infant may be maintained within a selectable temperature range. The heater canopy also includes an attachment member configured to secure the heater canopy to a wall during operation.

In another embodiment, a system includes a steam generator configured to provide steam generated electricity; and a heater canopy operatively connected to the steam generator. The heater canopy includes a solar panel configured to provide solar generated electricity, and a heater operatively connected to the solar panel and the steam generator. The heater is powered by the steam generated electricity and/or the solar generated electricity. The heater is configured to provide radiant energy in the infrared spectrum to impinge upon and thereby warm an infant. The heater canopy also includes a controller operatively connected to the heater. The controller is configured to regulate the temperature of the heater such that the infant may be maintained within a selectable temperature range.

Various other features, objects, and advantages of the invention will be made apparent to those skilled in the art from the accompanying drawings and detailed description thereof.

### BRIEF DESCRIPTION OF THE DRAWINGS

FIG. 1 is a schematic representation of a an infant warmer in accordance with an embodiment;

FIG. 2 is an isometric view of a heater in accordance with an embodiment; and

FIG. 3 is a schematic representation of a steam generator in accordance with an embodiment.

### DETAILED DESCRIPTION OF THE INVENTION

In the following detailed description, reference is made to the accompanying drawings that form a part hereof, and in which is shown by way of illustration specific embodiments that may be practiced. These embodiments are described in sufficient detail to enable those skilled in the art to practice the embodiments, and it is to be understood that other embodiments may be utilized and that logical, mechanical, electrical and other changes may be made without departing from the scope of the embodiments. The following detailed description is, therefore, not to be taken as limiting the scope of the invention.

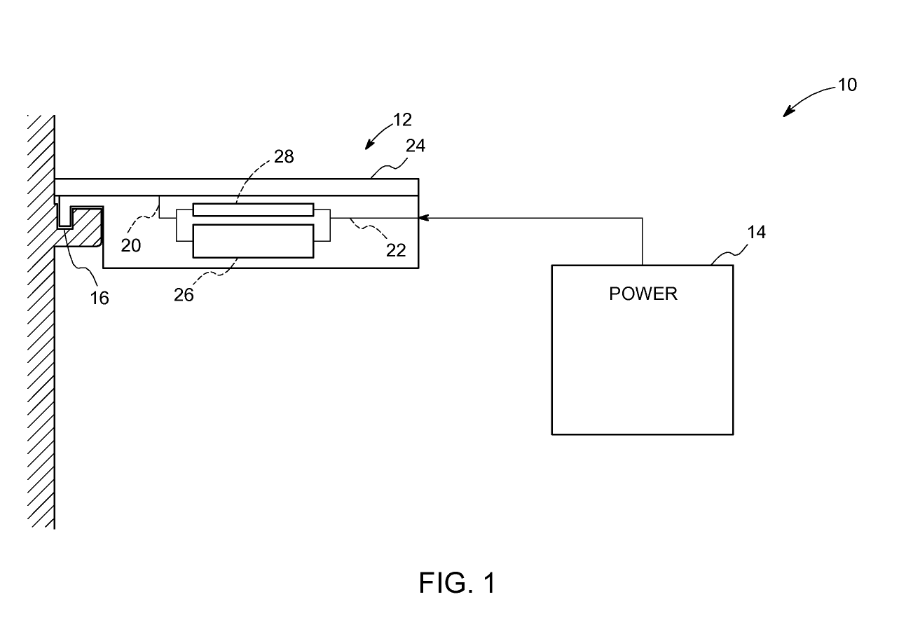

Referring to FIG. 1, an infant warmer 10 is shown in accordance with one embodiment. The infant warmer 10 may include a heater canopy 12 and a supplemental power supply 14. The supplemental power supply 14 will hereinafter be described as a steam generator, however alternate power supplies can be envisioned.

The heater canopy 12 may be adapted for attachment to a wall such as with the wall attachment member 16 or any other known engagement mechanism. After being attached to a wall, the heater canopy 12 can be positioned above and in sufficiently close proximity to a baby such that the baby is warmed in a manner that is consistent with applicable regulatory/safety requirements. Advantageously the wall attachment feature enables a more compact, lightweight and inexpensive infant warmer as compared to more conventional designs incorporating additional structure such as a frame, base, crib, bed, etc. The heater canopy 12 may include a first electrical conductor 20, a second electrical conductor 22, a photovoltaic panel or solar panel 24, a heater 26, and a controller 28.

The first electrical conductor 20 is adapted to electrically couple the solar panel 24 with the heater 26 and the controller 28 such that the heater 26 and the controller 28 can be powered. The second electrical conductor 22 is adapted to electrically couple the steam generator 14 with the heater 26 and the controller 28 such that the heater 26 and the controller 28 can be powered. The solar panel 24 is adapted to use photons from the sun to generate electricity through photovoltaic effect. The solar panel 24 may, for example, comprise wafer-based crystalline silicon cells or a thin-film cell based on cadmium telluride or silicon. It should be appreciated that solar energy is inexpensive and abundantly available. The availability of solar energy renders the solar panel 24 a practical energy source in developing countries in which other sources of electricity may be unavailable or unreliable.

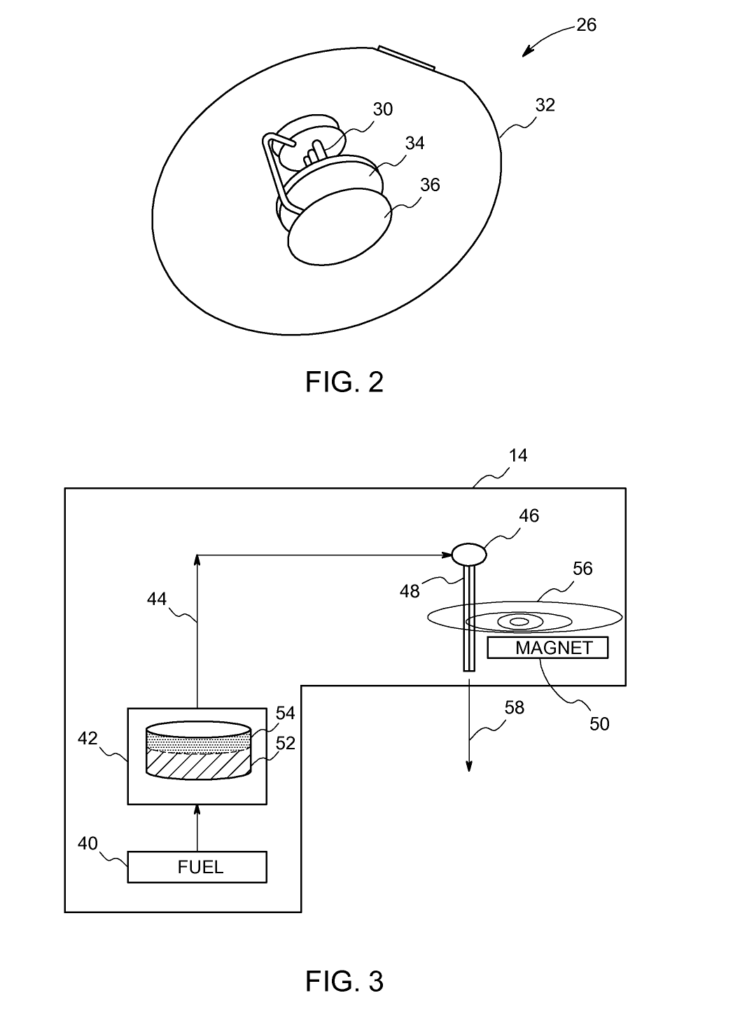

Referring to FIG. 2, a detailed isometric view of the heater 26 is shown accordance with an embodiment. The heater 26 will hereinafter be described as a radiant heater device configured to provide radiant energy in the infrared spectrum to impinge upon an infant. It should, however, be appreciated that the infant warmer 10 could be configured to implement a variety of different heater types and configurations. According to the depicted embodiment, the radiant heater 26 includes an infrared emitter 30 that provides the infrared radiation that is reflected towards an infant by means of a reflector 32. The reflector 32 is preferable of a particular geometric configuration such as an ellipsoid, a paraboloid or a hyperboloid. A deflector 34 may be used to deflect some of the infrared energy otherwise directed toward an infant back toward and then re-reflected from the reflector 32. A heat shield 36 may be mounted on the downward side of the deflector 34 to prevent the high temperature of the deflector 34 from being accessible by the user.

Referring again to FIG. 1, the controller 28 is operatively connected to the first electrical conductor 20 and the second electrical conductor 22 such that the controller 28 can receive electricity from either the solar panel 24 or the steam generator 14. The controller 28 is also operatively connected to the heater 26 and is configured to regulate the temperature of the heater 26. Accordingly, based on the position of the heater 26 relative to the infant to be warmed, the controller can be implemented to establish a predetermined optimal temperature range at which the infant is maintained. The controller 28 may comprise a computer and a user interface such as a rotary dial, keyboard, number pad, touch screen, etc.

The controller 28 may also be implemented to select between the multiple power sources (i.e., the solar panel 24 and the steam generator 14) to ensure the heater 26 remains adequately powered. As an example, the controller 28 may implement the solar panel 24 as the exclusive source of power until the solar panel 24 is unable to meet the power demands of the heater 26. If the solar panel 24 becomes unable to meet the heater's 26 power demands (e.g., at night), the controller 28 may implement the steam generator 14 by itself or in combination with the solar panel 24 to power the heater 26.

Referring to FIG. 3, the steam generator 14 is shown in accordance with an embodiment is provided. The steam generator 14 is an optional component adapted to power the infant warmer 10 when the solar panel 24 is not operational (e.g., at night). The steam generator 14 includes a fuel source 40, a steam chamber 42, a conduit or pipe 44, a pivot point 46, a hollow conductor 48 and a magnet 50.

The fuel source 40 comprises an ignitable resource for generating heat. It is envisioned that the fuel source 40 may comprise firewood; biogas; compressed natural gas (CNG); liquefied petroleum gas (LPG); kerosene; or any other type of fuel that exists in a solid/liquid/gaseous form that is readily available in rural areas. The availability of the fuel source 40 renders the infant warmer 10 particularly well suited for use in developing countries in which other fuel sources may be limited. The steam chamber 42 comprises water 52 and or steam 54. The steam chamber 42 is in fluid communication with the conduit 44, the pivot point 46 and the hollow conductor 48.

The water 52 in the steam chamber 42 is convertible to steam 54 when exposed to heat from the fuel source 40. The introduction of heat and subsequent conversion from water 52 to steam 54 generates pressure within the steam chamber 42. This pressure forces the steam 54 through the conduit 44, through the pivot point 46, and through the hollow conductor 48. The transfer of steam through the hollow conductor 48 causes the hollow conductor 48 to deflect and thereby pivot about the pivot point 46.

The magnet 50 generates a magnetic field 56. The hollow conductor 48 is disposed within the magnetic field 56, and the motion of the hollow conductor 48 within the magnetic field 56 generates current 58. According to another embodiment, the steam generator 14 may implement a steam turbine (not shown) operatively connected to and configured to drive an electric generator in order to produce current.

This written description uses examples to disclose the invention, including the best mode, and also to enable any person skilled in the art to practice the invention, including making and using any devices or systems and performing any incorporated methods. The patentable scope of the invention is defined by the claims, and may include other examples that occur to those skilled in the art. Such other examples are intended to be within the scope of the claims if they have structural elements that do not differ from the literal language of the claims, or if they include equivalent structural elements with insubstantial differences from the literal language of the claims.

I claim:

1. A heater canopy for a warmer system comprising:
a solar panel configured to convert solar energy into electricity;
a heater operatively connected to the solar panel, said heater powered by the electricity from the solar panel, said heater configured to provide radiant energy in the infrared spectrum to impinge upon and thereby warm an infant;
a controller operatively connected to the heater, said controller configured to regulate the temperature of the heater such that the infant may be maintained within a selectable temperature range; and
an attachment member configured to secure the heater canopy to a wall during operation.

2. The heater canopy of claim 1, wherein the solar panel comprises wafer-based crystalline silicon cells.

3. The heater canopy of claim 1, wherein the heater is operatively connected to a supplemental power source adapted to provide power at night.

4. The heater canopy of claim 3, wherein the supplemental power source comprises a steam generator.

5. The heater canopy of claim 4, wherein the steam generator is configured to transmit steam through a hollow conductor disposed in a magnetic field.

6. The heater canopy of claim 4, wherein the steam generator comprises a steam turbine operatively connected to an electrical generator.

7. The heater canopy of claim 4, wherein the controller is configured to select between the solar panel and the steam generator to ensure the heater remains powered during the day and at night.

8. The heater canopy of claim 1, wherein the heater comprises an infrared emitter and a reflector.

9. A system comprising:
a steam generator configured to provide steam generated electricity; and
a heater canopy operatively connected to the steam generator, said heater canopy comprising:
a solar panel configured to provide solar generated electricity;
a heater operatively connected to the solar panel and the steam generator, said heater powered by the steam generated electricity and/or the solar generated electricity, said heater configured to provide radiant energy in the infrared spectrum to impinge upon and thereby warm an infant; and
a controller operatively connected to the heater, said controller configured to regulate the temperature of the heater such that the infant may be maintained within a selectable temperature range.

10. The system of claim 9, wherein the steam generator is configured to transmit steam through a hollow conductor disposed in a magnetic field in order to provide the steam generated electricity.

11. The system of claim 9, wherein the steam generator comprises a steam turbine operatively connected to an electrical generator.

12. The system of claim 9, wherein the steam generator is adapted to implement a fuel source that is readily available in developing countries.

13. The system of claim 9, wherein the steam generator uses firewood to generate heat and thereby convert water into steam.

14. The system of claim 9, wherein the steam generator uses a solid/liquid/gaseous form of fuel comprising one of a biogas; compressed natural gas; liquefied petroleum gas; and kerosene to generate heat and thereby convert water into steam.

15. The system of claim 9, wherein the controller is configured to select between the solar panel and the steam generator to ensure the heater remains powered during the day and at night.

16. The system of claim 9, wherein the solar panel comprises wafer-based crystalline silicon cells.

17. The system of claim 9, wherein the heater canopy comprising an attachment member configured to secure the heater canopy to a wall during operation.
